(19) United States
(12) Patent Application Publication
(10) Pub. No.: US 2015/0028352 A1
(43) Pub. Date: Jan. 29, 2015

(54) SEMICONDUCTOR DEVICE

(71) Applicant: ROHM CO., LTD., Kyoto-shi, Kyoto (JP)

(72) Inventor: Keiji Okumura, Kyoto-shi (JP)

(21) Appl. No.: 14/379,152

(22) PCT Filed: Feb. 15, 2013
(86) PCT No.: PCT/JP2013/053664

§ 371 Date: Aug. 15, 2014

(30) Foreign Application Priority Data
Feb. 17, 2012 (JP) 2012-033253

(51) Int. Cl. H01L 29/78; H01L 29/10; H01L 29/16

(52) U.S. Cl. CPC H01L 29/7849; H01L 29/1608; H01L 29/1033
USPC 257/77

(57) ABSTRACT

[Object] To provide a semiconductor device with which an increase in on-resistance can be suppressed even if a voltage is continuously applied for a long period of time across a source and a drain in a gate-off state.

[Solution Means] A semiconductor device 1 includes a substrate 7 made of an n+ type SiC and having a predetermined off-angle, a drift layer 8 made of an n⁻ type SiC and formed on the substrate 7, a plurality of unit cells 10 demarcated in the drift layer 8 by n⁻ type epitaxial lines 13 including first lines 11 parallel to an off-direction of the substrate 7 and second lines 12 intersecting the first lines 11, a gate insulating film 17 formed on the drift layer 8, a gate electrode 18 formed on the gate insulating film 17, and a p⁻ type relaxation layer 24 formed in the first lines 11 in the drift layer 8 and relaxing an electric field generated in the gate insulating film 17.

### TECHNICAL FIELD

The present invention relates to a semiconductor device and, to be more specific, relates to an SiC power device to be used in the power electronics field.

### BACKGROUND ART

For example, an SiC semiconductor device described in Patent Document 1 is known.

The SiC semiconductor device of Patent Document 1 includes an n⁺ type SiC substrate, an n⁻ type drift layer formed on the n⁺ type SiC substrate, a p type base region formed on a front surface of the n⁻ type drift layer, and an n⁺ type source region formed on a front surface of an interior of the p type base region. A gate electrode is formed via a gate insulating film on the front surface of the front surface of the n⁻ type drift layer and the front surface of the p type base region. A portion of the front surface of the n⁺ type source region is connected to a source electrode. On the other hand, a drain electrode is formed on a rear surface side of the n⁺ type SiC substrate. The SiC semiconductor substrate is thereby arranged as a vertical type power MOSFET with which an n type channel region is formed on the front surface of the n⁻ type drift layer so as to connect from the n⁺ type source region in the interior of the p type base region to an n⁺ type source region in an adjacent p type base region.

### CITATION LIST

### Patent Document

Patent Document 1: Japanese Patent Application Publication No. 2003-347548

### SUMMARY OF THE INVENTION

### Problems to be Solved by the Invention

An object of the present invention is to provide a semiconductor device that is excellent in voltage resistance and can be manufactured at high yield.

Also, another object of the present invention is to provide a semiconductor device with which an increase in on-resistance can be suppressed even if a voltage is continuously applied for a long period of time across a source and a drain in a gate-off state.

### Means for Solving the Problems

A semiconductor device according to one aspect of the present invention for achieving the above object includes a substrate made of a first conductivity type SiC and having a predetermined off-angle, an epitaxial layer made of a first conductivity type SiC and formed on a front surface of the substrate, a plurality of unit cells demarcated in the epitaxial layer by first conductivity type epitaxial lines, including a first line parallel to an off-direction of the substrate and a second line intersecting the first line, and each having a first conductivity type source region, forming a portion of a front surface of the epitaxial layer, and a second conductivity type channel region, formed on a rear surface side of the epitaxial layer with respect to the source region so as to contact the source region and forming a portion of the front surface of the epitaxial layer, a gate insulating film formed on the front surface of the epitaxial layer, a gate electrode formed on the gate insulating film and facing the channel region across the gate insulating film, and an electric field relaxation portion formed in the first line in the epitaxial layer and relaxing an electric field generated in the gate insulating film (Claim 1).

The inventor of this application found that with a conventional vertical type power MOSFET, it is difficult to manufacture a device of excellent voltage resistance at a high yield. For example, in an extremely large number of cases, a gate insulating film disposed between mutually adjacent unit cells undergoes dielectric breakdown after a high-temperature reverse bias (HTRB) test, which is one of the quality assurance tests. Consequently, there are cases where many products cannot meet the voltage resistance standard for a non-defective product and are judged to be defective products. The inventor of this application thus diligently examined the cause of dielectric breakdown of the gate insulating film in the HTRB test and in actual use, etc. It was thereby found that the cause is a concentration of electric field with respect to the gate insulating film. An HTRB test is a test with which the voltage resistance of a device is checked by continuously applying a voltage approximating a device withstand voltage across a source and drain for a long period of time in a gate-off state under high temperature.

With the semiconductor device according to the present invention, in a vertical structure in which the source region of the first conductivity type and the substrate (drain) of the first conductivity type are disposed in a vertical direction across the channel region of the second conductivity type, the electric field relaxation portion that relaxes the electric field generated in the gate insulating film is formed in the first conductivity type epitaxial line between mutually adjacent unit cells. Dielectric breakdown of the gate insulating film can thus be prevented even if a voltage is continuously applied for a long period of time across the source and the drain in the gate-off state. Therefore, with the arrangement of the present invention, a semiconductor that is excellent in voltage resistance can be manufactured at high yield.

Moreover, the electric field relaxation portion is formed in the first line that is parallel to the off-direction of the substrate. It was found that in this case, an increase in on-resistance can be suppressed even if a voltage is continuously applied for a long period of time across the source and the drain in the gate-off state. The electric field relaxation portion may thus also be referred to as a resistance increase preventing portion.

Also, preferably with the semiconductor device, the electric field relaxation portion is formed so as to cross the first line in a width direction to selectively partition the first line (Claim 2). By this arrangement, the increase in on-resistance can be suppressed further. In this case, preferably, the length of each partitioned first line is no more than the length of the second line (Claim 3).

Also, preferably with the semiconductor device, the electric field relaxation portion is disposed at an intersection portion of the first line and the second line (Claim 4). Dielectric breakdown of the gate insulating film at the intersection portion of the first line and the second line, at which dielectric breakdown of the gate insulating film occurs especially readily, can be prevented effectively because the electric field relaxation portion is disposed at the intersection portion. More preferably in this case, the electric field relaxation portion that is disposed at the intersection portion is overlapped with the channel region in plan view (Claim 5).

Also, with the semiconductor device, the electric field relaxation portion may be formed along the first line and to have a width narrower than the width of the first line (Claim 6).

Also, with the semiconductor device, the electric field relaxation portion is preferably a second conductivity type relaxation layer formed by introducing impurity ions of a second conductivity type into the first line (Claim 7). By the second conductivity type relaxation layer that differs in conductivity type from the first conductivity type epitaxial line, a depletion layer, resulting from a junction (pn junction) of the second conductivity type relaxation layer and the first conductivity type epitaxial line, can be formed in the first conductivity type epitaxial line. By the depletion layer, an equipotential surface of high electric potential on the basis of the gate electrode can be distanced from the gate insulating film. Consequently, the electric field applied to the gate insulating film can be decreased to prevent dielectric breakdown. In this case, the second conductivity type relaxation layer may contain aluminum (Al) or boron (B) as the second conductivity type impurity ions (Claim 8). Also, the second conductivity type relaxation layer may be made high in resistance (Claim 9), and in this case, the second conductivity type relaxation layer that has been made high in resistance may contain aluminum (Al), boron (B), argon (Ar), or vanadium (V) as the second conductivity type impurity ions (Claim 10).

Also, the semiconductor device may include a first comb-type unit formed by integrally joining a plurality of unit cells in a comb-teeth shape and a second comb-type unit formed by integrally joining a plurality of unit cells in a comb-teeth shape and engaging with the first comb-type unit, and in this case, the first conductivity epitaxial lines are preferably formed in a winding shape so as to meander between the first comb-type unit and the second comb-type unit (Claim 11).

Also, preferably with the semiconductor device, the plurality of unit cells are in a staggered alignment in which mutually adjacent unit cells are alternately dislocated along the second line (Claim 12).

Also, with the semiconductor device, each unit cell may be formed to a square shape (Claim 13) or to an oblong shape having a long side extending along the second line and a short side extending along the first line (Claim 14). Further, each unit cell may be formed to a polygonal shape (more preferably a regular polygonal shape), such as a hexagonal shape (Claim 15) or a triangular shape (Claim 16), etc., or to a circular shape (Claim 17).

Also, a semiconductor device according to another aspect of the present invention for achieving the above object includes a substrate made of a first conductivity type SiC having a predetermined off-angle, an epitaxial layer made of a first conductivity type SiC and formed on a major surface of the substrate, a plurality of unit cells demarcated in the epitaxial layer by first conductivity type epitaxial lines, including a first line and a second line respectively intersecting the off-direction of the substrate and intersecting each other, and each having a first conductivity type source region, forming a portion of a front surface of the epitaxial layer, and a second conductivity type channel region, formed on a rear surface side of the epitaxial layer with respect to the source region so as to contact the source region forming a portion of the front surface of the epitaxial layer, a gate insulating film formed on the front surface of the epitaxial layer, and a gate electrode formed on the gate insulating film and facing the channel region across the gate insulating film (Claim 18).

With this arrangement, both the first line and the second line that form the first conductivity epitaxial lines intersect the off-direction of the substrate. That is, neither the first line nor the second line is parallel to the off-direction of the substrate. An increase in the on-resistance can thus be suppressed even without having to form an electric field relaxation portion in the first line or the second line.

With the semiconductor device according another aspect, an electric field relaxation portion, which relaxes an electric field generated in the gate insulating film, may be formed so as to cross the first line and/or the second line in a width direction to selectively partition the first line and/or the second line. In this case, a preferable arrangement of the semiconductor device according to the one aspect described above (Claims 3 and 4 and Claims 7 to 10) may be adopted in regard to the electric field relaxation portion.

Also, the semiconductor device according to another aspect may further include a second electric field relaxation portion formed along the first line and/or the second line in the epitaxial layer and having a width narrower than the respective widths of the first line and the second line, and in this case, the second electric field relaxation portion may be connected integrally to the electric field relaxation portion described above.

Also, with the semiconductor device according to the other aspect, a preferable arrangement of the semiconductor device according to the one aspect described above (Claims 11 to 17) may be adopted in regard to the unit cells.

Also, a semiconductor device according to yet another aspect of the present invention for achieving the above object includes a substrate made of a first conductivity type SiC and having a predetermined off-angle, an epitaxial layer made of a first conductivity type SiC and formed on a front surface of the substrate, a plurality of unit cells demarcated in the epitaxial layer by first conductivity type epitaxial lines, including a first line parallel to an off-direction of the substrate and a second line intersecting the first line, and each having a first conductivity type source region, forming a portion of a front surface of the epitaxial layer, and a second conductivity type channel region, formed on a rear surface side of the epitaxial layer with respect to the source region so as to contact the source region and forming a portion of the front surface of the epitaxial layer, a gate insulating film formed on the front surface of the epitaxial layer, a gate electrode formed on the gate insulating film and facing the channel region across the gate insulating film, and a damage layer formed in the epitaxial layer so as to cross the first line in a width direction to selectively partition the first line and having properties different from those of other portions of the epitaxial layer (Claim 19).

With this arrangement, the damage layer is formed to cross the first line, parallel to the off-direction of the substrate, in the width direction (a direction intersecting the off-direction) and thereby selectively partition the first line. An increase in the on-resistance can thus be suppressed without having to form an electric field relaxation portion in the first line or the second line.

With the semiconductor device according to yet another aspect, an electric field relaxation portion, which relaxes an electric field generated in the gate insulating film, may be formed so as to cross the first line and/or the second line in a width direction to selectively partition the first line and/or the second line. In this case, a preferable arrangement of the semiconductor device according to the one aspect described above (Claims 3 and 4 and Claims 7 to 10) may be adopted in regard to the electric field relaxation portion.

Also, the semiconductor device according to yet another aspect may further include a second electric field relaxation portion formed along the first line and/or the second line in the epitaxial layer and having a width narrower than the respective widths of the first line and the second line, and in this case, the second electric field relaxation portion may be connected integrally to the electric field relaxation portion described above.

Also, with the semiconductor device according to another aspect, a preferable arrangement of the semiconductor device according to the one aspect described above (Claims 11 to 17) may be adopted in regard to the unit cells.

Also, the off-direction of the substrate is preferably the <11-20> direction (Claim 20).

### BRIEF DESCRIPTION OF THE DRAWINGS

FIGS. 1A and 1B are schematic plan views of a semiconductor device according to a first preferred embodiment of the present invention, with FIG. 1A being an overall view and FIG. 1B being a layout diagram of a plurality of unit cells.

FIGS. 2A and 2B are sectional views respectively taken along sectioning line A-A and sectioning line B-B in FIG. 1B.

FIG. 3 is a schematic view of the substrate and the drift layer (epitaxial layer) in the wafer state.

FIG. 4 is a schematic view of a unit cell of a 4H-SiC crystal structure.

FIG. 5 is a diagram of viewing the unit cell from directly above a (0001) surface.

FIG. 6 shows enlarged views of principal portions of the substrate and the drift layer, with FIG. 6A being a plan view and FIG. 6B being a sectional view taken along sectioning line C-C in FIG. 6A.

FIG. 7 is another layout diagram of the plurality of unit cells.

FIG. 8 is another layout diagram of the plurality of unit cells.

FIG. 9 is another layout diagram of the plurality of unit cells.

FIG. 10 is another layout diagram of the plurality of unit cells.

FIG. 11 is another layout diagram of the plurality of unit cells.

FIG. 12 is another layout diagram of the plurality of unit cells.

FIGS. 13A and 13B are schematic plan views of a semiconductor device according to a second preferred embodiment of the present invention, with FIG. 13A being an overall view and FIG. 13B being a layout diagram of a plurality of unit cells.

FIG. 14 is a sectional view taken along sectioning line D-D in FIG. 13B.

FIG. 15 is another layout diagram of the plurality of unit cells.

FIG. 16 is another layout diagram of the plurality of unit cells.

FIG. 17 is another layout diagram of the plurality of unit cells.

FIG. 18 is another layout diagram of the plurality of unit cells.

FIG. 19 is another layout diagram of the plurality of unit cells.

FIG. 20 is another layout diagram of the plurality of unit cells.

FIGS. 21A and 21B are schematic plan views of a semiconductor device according to a third preferred embodiment of the present invention, with FIG. 21A being an overall view and FIG. 21B being a layout diagram of a plurality of unit cells.

FIGS. 22A and 22B are sectional views respectively taken along sectioning line E-E and sectioning line F-F in FIG. 21B.

FIGS. 23A and 23B are schematic plan views of a semiconductor device according to a fourth preferred embodiment of the present invention, with FIG. 23A being an overall view and FIG. 23B being a layout diagram of a plurality of unit cells.

FIGS. 24A and 24B are sectional views respectively taken along sectioning line G-G and sectioning line H-H in FIG. 23B.

### MODES FOR CARRYING OUT THE INVENTION

Preferred embodiments of the present invention shall now be described in detail with reference to the attached drawings.

### First Preferred Embodiment

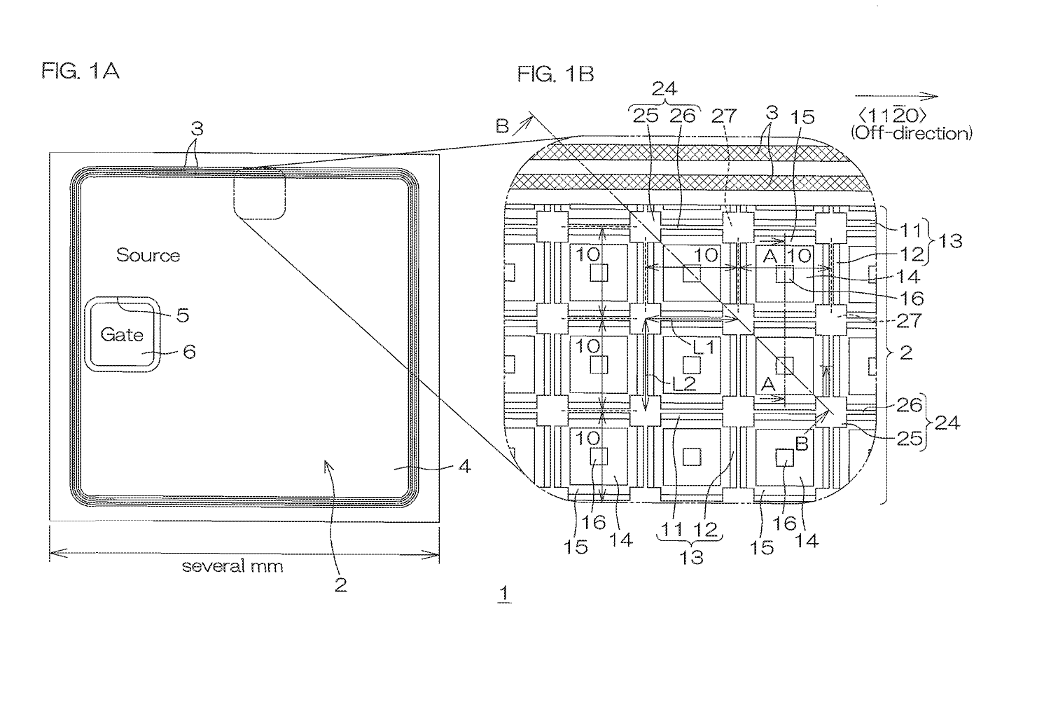

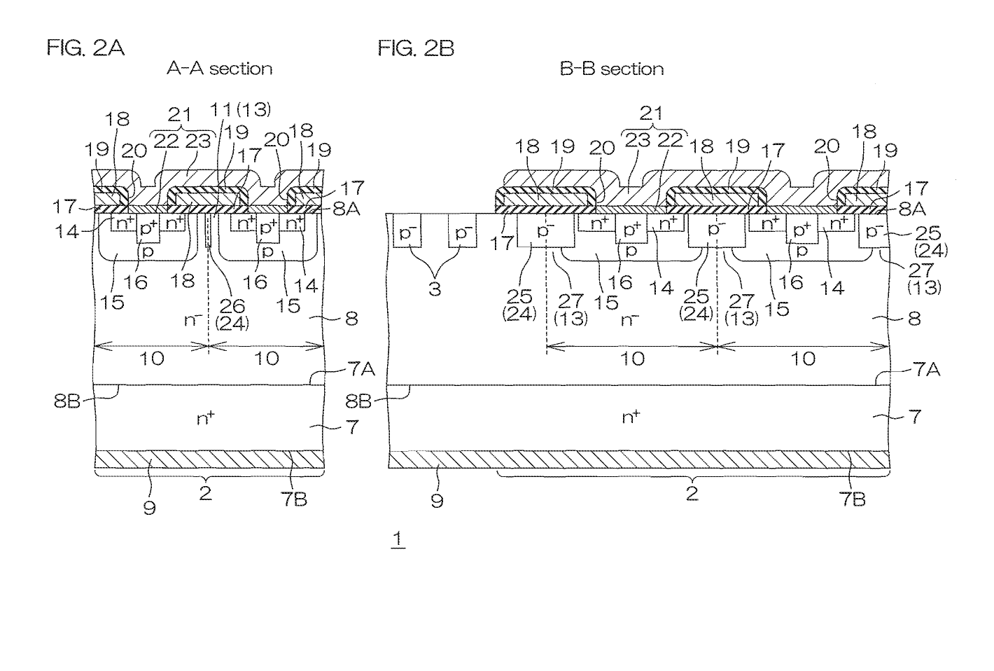

FIGS. 1A and 1B are schematic plan views of a semiconductor device according to a first preferred embodiment of the present invention, with FIG. 1A being an overall view and FIG. 1B being a layout diagram of a plurality of unit cells. FIGS. 2A and 2B are sectional views respectively taken along sectioning line A-A and sectioning line B-B in FIG. 1B. In FIG. 1B, a portion of the semiconductor device 1 is drawn transparently for the sake of clarity.

The semiconductor device 1 includes a planar gate type VDMISFET (Vertical Double-diffused Metal Insulator Field Effect Transistor) in which SiC is adopted. The outer shape of the semiconductor device 1 is, for example, a chip shape of square shape in plan view as shown in FIG. 1A. The size of the chip-shaped semiconductor device 1 is such that the length in each of the up, down, right, and left directions on the paper surface of FIG. 1A is approximately several mm. An active region 2 is set on a front surface of the semiconductor device 1. The active region 2 is a region that is demarcated by being surrounded by a guard ring 3.

Also, a source pad 4 is formed on the front surface of the semiconductor device 1. The source pad 4 has a substantially square shape in plan view with its four corners curving outward and is formed to cover substantially the entirety of the front surface of the semiconductor device 1. In the source pad 4, a removed region 5 is formed near the center of one of its sides. The removed region 5 is a region in which the source pad 4 is not formed.

A gate pad 6 is disposed in the removed region 5. An interval is set between the gate pad 6 and the source pad 4 and these are mutually insulated from each other.

The internal structure of the semiconductor device 1 shall now be described.

The semiconductor device 1 includes a substrate 7 made of an n⁺ type SiC and a drift layer 8 (drain layer) made of an n⁻ type SiC and laminated on a front surface 7A of the substrate 7. The drift layer 8 is an epitaxial layer formed by epitaxially growing SiC on the front surface 7A of the substrate 7. Also, a drain electrode 9 is formed on a rear surface 7B of the substrate 7 so as to cover the entirety thereof.

A plurality of unit cells 10 are laid out at a vicinity of a front surface 8A (at a front surface portion) of the drift layer 8. The plurality of unit cells 10 are demarcated by n⁻ type epitaxial lines 13 that include first lines 11 and second lines 12 that intersect each other. Each n⁻ type epitaxial line 13 is a portion where an n⁻ type portion of the drift layer 8 is selectively exposed in the shape of a line at the front surface 8A. In the present preferred embodiment, the n⁻ type epitaxial lines 13 form a lattice by the first lines 11 and the second lines 12 intersecting each other orthogonally, and boundaries between mutually adjacent unit cells 10 are set at centers in width directions of the n⁻ type epitaxial lines 13. The plurality of unit cells 10 are thereby laid out in an array. Also, each n⁻ type epitaxial line 13 extends between mutually adjacent unit cells 10. Also, with the present preferred embodiment, each unit cell 10 is formed to a square shape by a lattice window portion demarcated by the n⁻ type epitaxial lines 13 being formed to a square shape.

Each unit cell 10 includes an n⁺ type source region 14, a p type channel region (well region) 15, and a p+ type channel contact region 16. A drain of the semiconductor device 1 is made of a portion of the drift layer 8 that spreads below the plurality of unit cells 10 and is shared by the plurality of unit cells 10. In the present preferred embodiment, the source region 14 is formed so as to form a portion of the front surface 8A of the drift layer 8, and the channel region 15 is formed so as to surround the lower side and the sides of the source region 14. The channel region 15 thus contacts the source region 14 at a rear surface 8B side of the drift layer 8 with respect to the source region 14 and forms a portion of the front surface 8A of the drift layer 8. The channel contact region 16 penetrates through a portion (for example, a central portion) of the source region 14 and contacts the channel region 15.

The n⁻ type epitaxial lines 13, including the first lines 11 and the second lines 12, are disposed at the sides of the channel regions 15. One side of each unit cell 10 having the source region 14 and the channel region 15 is a first line 11 and another side is a second line 12. Movement by an amount corresponding to a unit along the first line 11 or the second line 12 results in an adjacent unit cell 10. Movement by an amount corresponding to an integral multiple of a unit along the first line 11 or the second line 12 also results in an adjacent unit cell 10.

A gate insulating film 17 is formed along the n⁻ type epitaxial lines 13 on the front surface 8A of the drift layer 8. The gate insulating film 17 extends between mutually adjacent unit cells 10 and covers a portion of the channel region 15 that surrounds the source region 14 (peripheral edge portion of the channel region 15) and an outer peripheral edge of the source region 14. A gate electrode 18 is formed on the gate insulating film 17. The gate electrode 18 faces the peripheral edge portion of the channel region 15 across the gate insulating film 17. In each unit cell 10, an annular channel is formed at the peripheral edge portion of the channel region 15 by controlling a voltage applied to the gate electrode 18. A drain current flowing in an n⁻ type epitaxial line 13 toward the front surface 8A along a side surface of the channel region 15 can thereby be made to flow into the source region 14 via the channel.

Also, an interlayer insulating film 19 is formed on the front surface 8A of the drift layer 8 so as to cover the gate electrode 18. A contact hole 20 that selectively exposes the source region 14 and the channel contact region 16 is formed in the interlayer insulating film 19.

A source electrode 21 is formed on the interlayer insulating film 19. The source electrode 21 contacts the channel contact regions 16 and the source regions 14 of all unit cells 10 together via the respective contact holes 20. That is, the source electrode 21 is an electrode in common to all unit cells 10. The source electrode 21 is electrically connected via an unillustrated source wiring, etc., to the source pad 4 (see FIG. 1A). On the other hand, the gate pad 6 (see FIG. 1A) is electrically connected via an unillustrated gate wiring, etc., to the gate electrode 18.

The source electrode 21 has a structure in which a contact metal 22 and a front surface metal 23 are laminated in that order from the side of contact with the drift layer 8.

In the semiconductor device 1, a p− type relaxation layer 24 is formed as an electric field relaxation portion (second conductivity type relaxation layer) in the n⁻ type epitaxial lines 13. The p⁻ type relaxation layer 24 integrally includes first portions 25 disposed at intersection portions 27 of the first lines 11 and the second lines 12 and second portions 26 disposed at linear portions (portions besides the intersection portions 27) of the first lines 11 and the second lines 12.

The first portions 25 of the p⁻ type relaxation layer 24 are formed to cross the first lines 11 and the second lines 12 in the width directions at a width wider than the respective widths of the first lines 11 and the second lines 12. In the present preferred embodiment, each first portion 25 is formed to a shape larger than the corresponding intersection portion 27 so as to overlap with the unit cells 10 (channel regions 15) that surround the intersection portion 27. Each first line 11 that extends across a plurality of unit cells 10 is thereby partitioned into a plurality of lines at the respective intersection portions 27 as boundaries so that the length of each line is shorter than the length of the entirety. Meanwhile, each second line 12 that extends across a plurality of unit cells 10 is similarly partitioned into a plurality of lines at the respective intersection portions 27 as boundaries so that the length of each line is shorter than the length of the entirety. Although in the present preferred embodiment, the unit cell 10 is formed to a square shape and therefore the length L₁ of each partitioned first line 11 is equal to the length L₂ of each partitioned second line 12, the unit cell 10 may be made to have an oblong shape having a long side extending along the second line 12 and a short side extending along the first line 11 so that L₁<L₂.

The second portions 26 of the p⁻ type relaxation layer 24 are formed along the first lines 11 and the second lines 12 and to have a width narrower than the respective widths of the first lines 11 and the second lines 12. In the present preferred embodiment, each second portion 26 is formed across an interval from each channel region 15 of a plurality of mutually adjacent unit cells 10. By providing an interval between the second portion 26 and the channel region 15, a pathway can be secured for the drain current that flows through the n⁻ type epitaxial line 13 and along the side surface of each channel region 15 when the semiconductor device 1 is on. An increase in the on-resistance can thus be suppressed to enable satisfactory transistor operation to be performed. As long as the arrangement is such that a pathway for the drain current can be secured, the first portions 25 may be formed to have a width narrower than the respective widths of the first lines 11 and the second lines 12, and the second portions 26 may be formed to have a width wider than the respective widths of the first lines 11 and the second lines 12. Also, both the first portions 25 and the second portions 26 may be formed to have widths narrower or widths wider than the respective widths of the first lines 11 and the second lines 12. Furthermore, there is no need for the first portions 25 and the second portions 26 to be formed integrally and, for example, these may be formed to be separated from each other.

Details of the respective portions of the semiconductor device 1 shall now be described further.

The impurity concentrations of the respective conductivity types in the semiconductor device 1 are as follows. Specifically, the concentration of the n⁺ type SiC is 1×10¹⁸ to 1×10²¹ cm⁻³ and the concentration of the n⁻ type SiC is 1×10¹⁵ to 1×10¹⁷ cm⁻³. Also, the concentration of the p⁺ type SiC is 1×10¹⁸ to 1×10²¹ cm⁻³, the concentration of the p type SiC is 1×10¹⁶ to 1×10¹⁹ cm⁻³, and the concentration of the p⁻ type SiC is 1×10¹³ to 1×10¹⁸ cm⁻³.

The size of each unit cell 10 is, for example, such that the length in the up, down, right, and left directions of the paper surface of FIG. 1B is approximately 10 μm.

In regard to the width of the n⁻ type epitaxial lines 13, both the first lines 11 and the second lines 12 have a fixed width of approximately 2.8 μm.

The size of the source region 14 is, for example, such that the length in the up, down, right, and left directions of the paper surface of FIG. 1B is approximately 5.7 μm, and the size of the contact portion (opening width of the contact hole 20) is approximately 4.5 μm. Also, the depth of the source region 14 is, for example, approximately 0.25 μm.

The size of the channel region 15 is, for example, such that the length in the up, down, right, and left directions of the paper surface of FIG. 1B is approximately 7.2 μm. Also, the depth of the channel region 15 is, for example, approximately 0.65 μm.

The size of the channel contact region 16 is, for example, such that the length in the up, down, right, and left directions of the paper surface of FIG. 1B is approximately 2.2 μm. Also, the depth of the channel contact region 16 is, for example, approximately 0.35 μm.

The gate insulating film 17 is made of an insulating material, such as silicon oxide (SiO₂), silicon nitride (SiN), or silicon oxynitride (SiON), etc. Also, the thickness of the gate insulating film 17 is, for example, approximately 400 Å.

The gate electrode 18 is made of a conductive material, such as polysilicon, etc. In this case, it is preferable for impurity ions to be introduced at a high concentration in the polysilicon. Also, the thickness of the gate electrode 18 is, for example, approximately 6000 Å.

The interlayer insulating film 19 is made of an insulating material, such as silicon oxide (SiO₂), etc.

The contact metal 22 of the source electrode 21 is made, for example, of a laminated structure (Ti/TiN) of titanium (Ti) and titanium nitride, and the front surface metal 23 is made, for example, of aluminum.

The drain electrode 9 is made, for example, of a laminated structure (Ti/Ni/Au/Ag) of titanium (Ti), nickel (Ni), gold (Au), and silver (Ag).

The depth of the p⁻ type relaxation layer 24 is shallower than that of the channel region 15 and is, for example, approximately 0.6 μm. Also, in the present preferred embodiment, the p⁻ type relaxation layer 24 is formed by introducing p type impurity ions into the n⁻ type epitaxial lines 13. As the p type impurity ions, those of aluminum (Al) or boron (B) may be applied. As a layer for relaxing the electric field in the n⁻ type epitaxial lines 13, an i type (intrinsic semiconductor) relaxation layer having a concentration of no more than 1×10⁻¹⁶ cm⁻³ or a high-resistance relaxation layer having a sheet resistance of no less than 100 MΩ/□ may be provided in place of the p⁻ type relaxation layer 24. In a case where a high-resistance relaxation layer is to be provided, aluminum (Al), boron (B), argon (Ar), or vanadium (V) may be employed as an impurity. Also, an increase in the on-resistance can be suppressed by the p⁻ type relaxation layer 24 as the electric field relaxation portion and therefore the p⁻ type relaxation layer 24 may be referred to as a resistance increase preventing portion.

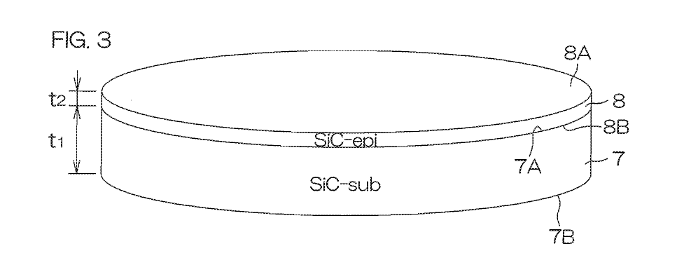

The relationship between an off-direction of the substrate 7 and the n⁻ type epitaxial lines 13 shall now be described with reference to FIG. 3 to FIG. 6. FIG. 3 is a schematic view of the substrate and the drift layer (epitaxial layer) in the wafer state.

SiC, which makes up the substrate 7 and the drift layer 8 (epitaxial layer) of the semiconductor device 1, is a material that exhibits crystal polymorph (polytype) and takes on various layer structures with the same composition and no less than 100 polytypes are present. As polytypes, for example, 4H-SiC, 3C-SiC, 6H-SiC, 15R-SiC, etc., are present. Among these, 4H-SiC is preferable. The description that follows is premised on the substrate 7 and the drift layer 8 being 4H-SiC.

The thickness t₁ of the substrate 7 is, for example, 200 μm to 500 μm, and the thickness t₂ of the drift layer 8 is thinner than that of the substrate 7 and is, for example, 5 μm to 100 μm (as one example, approximately 10 μm).

In the present preferred embodiment, the substrate 7 has an off-angle θ of 2° to 8° (preferably approximately 4°). For example, the front surface 7A (substrate major surface) of the substrate 7 is a surface that is inclined at the off-angle θ in a <11-20> direction (off-direction) with respect to a (0001) surface.

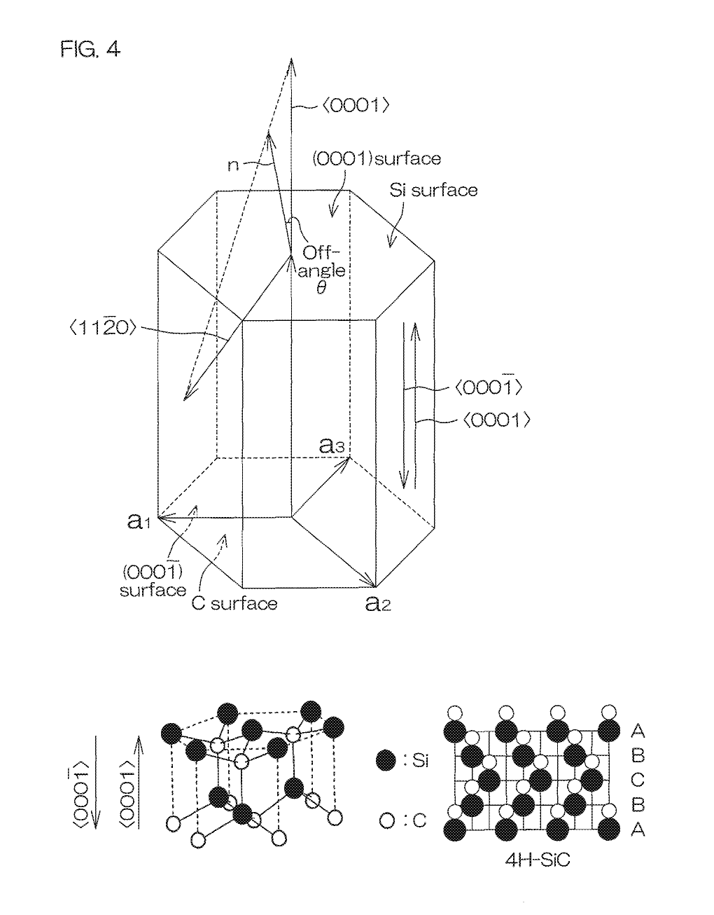

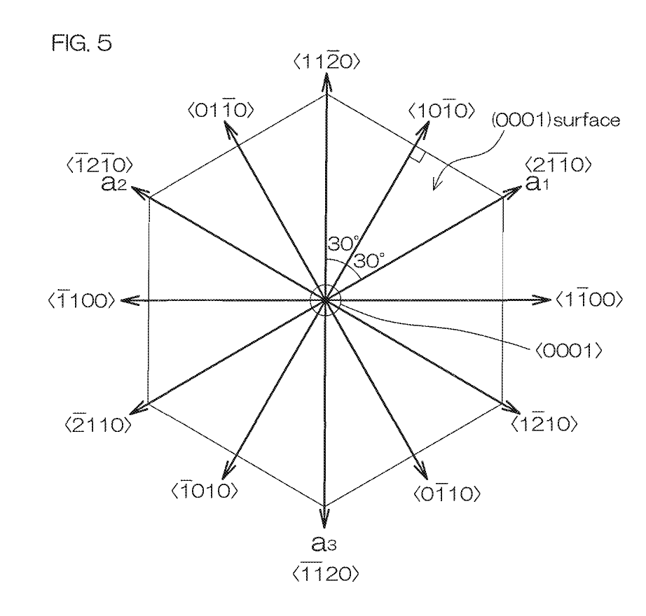

Expressions, such as (0001), <11-20>, etc., are so-called Miller indices that are used to describe lattice surfaces and lattice directions of an SiC crystal. The Miller indices can be described with reference to FIG. 4 and FIG. 5. Also, although with the present embodiment, a description shall be provided citing the <11-20> direction as an example of the off-direction, the off-direction may be changed as suited in accordance with the functions required of the semiconductor device 1.

FIG. 4 is a schematic view of a unit cell of the 4H-SiC crystal structure. FIG. 5 is a diagram of viewing the unit cell from directly above the (0001) surface. In the perspective view of the SiC crystal structure shown at the lower portion of FIG. 4, just two of the four layers of the SiC layer structure shown next to it are extracted.

As shown in FIG. 4, the crystal structure of 4H-SiC may be approximated by a hexagonal system with four carbon atoms bonded to a single silicon atom. The four carbon atoms are positioned at the four apices of a regular tetrahedron with the silicon atom disposed at the center. In regard to the four carbon atoms, the single carbon atom is positioned in the <0001> direction with respect to a silicon atom and the other three carbon atoms are positioned at the <000-1> side with respect to the silicon atom.

<0001> and <000-1> extend along the axial direction of a hexagonal prism, and the surface (top surface of the hexagonal prism) having <0001> as a normal is the (0001) surface (Si surface). On the other hand, the surface (bottom surface of the hexagonal prism) having <000-1> as a normal is the (000-1) surface (C surface).

Also, when viewed vertically along <0001> and from directly above the (0001) surface, respective directions passing through apices of the hexagonal prism that are not mutually adjacent are an a₁ axis <2-1-10>, an a₂ axis <−12-10>, and an a₃ axis <−1-120>.

As shown in FIG. 5, <11-20> is the direction passing through the apex between the a₁ axis and the a₂ axis, <−2110> is the direction passing through the apex between the a₂ axis and the a₃ axis, and <1-210> is the direction passing through the apex between the a₃ axis and the a₁ axis.

Axes, which, in respective intervals between the six axes passing through the respective apices of the hexagonal prism, are each inclined at an angle of 30° with respect to the respective axes at both sides thereof and are normals to the respective side surfaces of the hexagonal note, are, in clockwise order from the axis between the a₁ axis and <11-20>, <10-10>, <1-100>, <0-110>, <−1010>, <−1100>, and <01-10>. The respective surfaces (side surfaces of the hexagonal prism) having these axes as the normals are crystal surfaces perpendicular to the (0001) surface and the (000-1) surface.

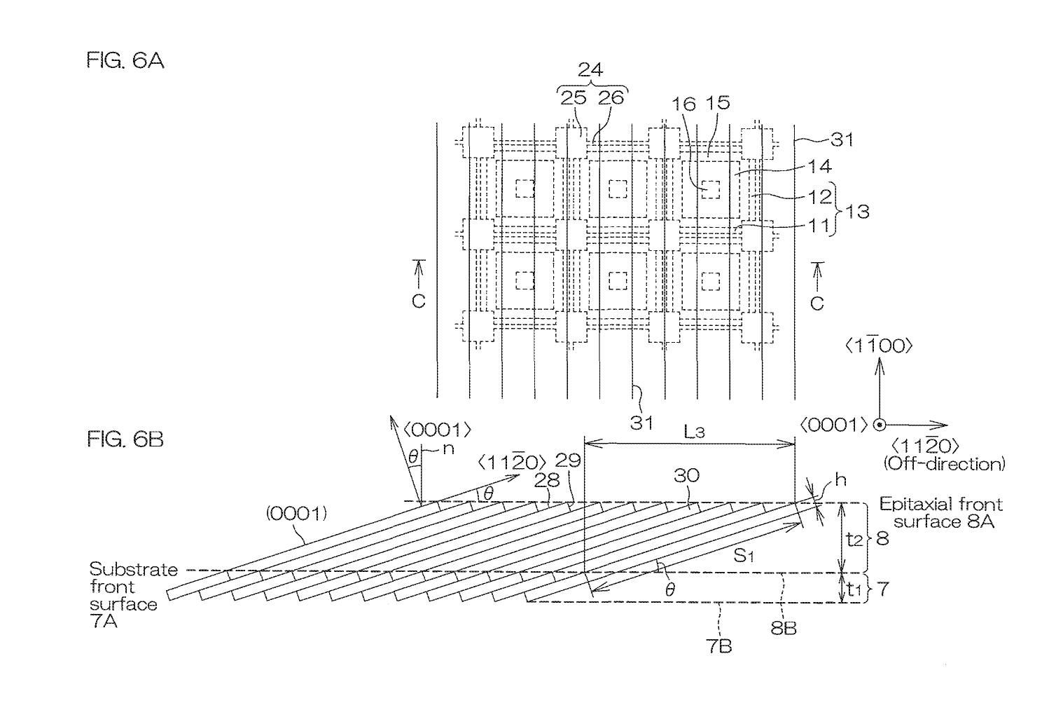

In the present preferred embodiment, the front surface 7A (major surface) of the substrate 7 is a surface that is inclined at the off-angle θ in the <11-20> direction with respect to the (0001) surface as shown in FIG. 6A.

FIG. 6 shows enlarged views of principal portions of the substrate and the drift layer, with FIG. 6A being a plan view and FIG. 6B being a sectional view taken along sectioning line C-C in FIG. 6A.

As shown in FIG. 6B, the direction of a normal n to the front surface 7A of the substrate 7 is not matched with the <0001> direction but is inclined at the off-angle θ of no more than 4° in the off-direction of <11-20> with respect to the (0001) surface. As shown in FIG. 4, the off-direction indicates the direction in which the normal n to the substrate 7 is inclined with respect to <0001> and is indicated by the direction of a vector resulting from projection of the normal n from <0001> onto the (0001) surface. That is, with the present preferred embodiment, the direction of the projection vector of the normal n is matched with <11-20>.

The substrate 7 is thus arranged from a plurality of layers 30 (bi-layers) having flat terrace surfaces 28, which are aligned regularly along <11-20> and with which the surface orientation is the (0001) surface, and step surfaces 29, which are formed at step portions of the terrace surfaces 28 that arise as a result of the front surface 7A being inclined with respect to the (0001) surface and with which the surface orientation is the (11-20) surface perpendicular to <11-20>, and the terrace surfaces 28 and the step surfaces 29 form the front surface 7A. Each layer 30 is arranged from a single atomic layer made up of the regular tetrahedrons, each formed by four carbon atoms being bonded to a single silicon atom, and the height thereof (step height h) is 0.25 nm.

As shown in FIG. 6A, the step surfaces 29 of the respective layers 30 are aligned regularly while maintaining the width of the terrace surfaces 28 in the <11-20> direction. Also, step lines 31, which are step edges of the step surfaces 29, are aligned in parallel while taking on the width of the terrace surfaces 28 while maintaining a perpendicular relationship with the <11-20> direction (in other words, while maintaining a parallel relationship with respect to the <1-100> direction).

The drift layer 8 is formed by the respective layers 30 undergoing crystal growth in a lateral direction along the <11-20> direction (off-direction) while maintaining the terrace surfaces 28 and the step surfaces 29 of the substrate 7. The width (step growth width S₁) of each layer 30 in the growth direction may be expressed, using the thickness t₂ of the drift layer 8, as t₂/sin θ. Also, the width (step advancement width L₃) of each layer 30 in the growth direction at the front surface 8A (epitaxial surface) of the drift layer 8 may be expressed as t₂/tan θ.

In the present preferred embodiment, a predetermined relationship is set between the n⁻ type epitaxial lines 13 of the drift layer 8 formed by epitaxial growth and the off-direction of the substrate 7. Specifically, among the lines making up the n⁻ type epitaxial lines 13, the first lines 11 are formed parallel to the off-direction of the substrate 7 and the second lines 12 are formed so as to be orthogonal to the off-direction of the substrate 7. That is, the first lines 11 extend along the <11-20> direction and the second lines 12 extend along the <1-100> direction.

As described above, with the semiconductor device 1, an annular channel is formed at the peripheral edge portion of the channel region 15 of each unit cell 10 by applying a drain voltage across the source electrode 21 and the drain electrode 9 (across the source and the drain) and applying a predetermined voltage to the gate electrode 18 in the state where the source electrode 21 is grounded. A current is thereby made to flow from the drain electrode 9 to the source electrode 21 and each unit cell 10 is put in an on state.

On the other hand, when the voltage across the source and drain is kept applied when each unit cell 10 is put in an off state (that is, the state in which the gate voltage is 0V), an electric field is applied to the gate insulating film 17 that is interposed between the gate electrode 18 and the drift layer 8. This electric field results from a potential difference between the gate electrode 18 and the drift layer 8. An equipotential surface of extremely high electric potential on the basis (0V) of the gate electrode 18 is distributed in the n⁻ type epitaxial lines 13 at which the conductivity type (n⁻ type) of the drift layer 8 is maintained and moreover, due to the small interval of equipotential surfaces, an extremely large electric field is generated. For example, when the drain voltage is 900V, an equipotential surface of 900V is distributed near the rear surface 7B of the substrate 7 in contact with the drain electrode 9 and although a voltage drop arises as the front surface 8A side of the drift layer 8 is approached from the rear surface 7B of the substrate 7, an equipotential surface of approximately several dozen V is distributed in the n⁻ type epitaxial lines 13. Therefore, an extremely large electric field directed toward the gate electrode 18 side is generated at the n⁻ type epitaxial lines 13.

Therefore, with the semiconductor device 1, the p⁻ type relaxation layer 24 of the opposite conductivity type (p⁻ type) as the drift layer 8 is formed across the entirety of the n⁻ type epitaxial lines 13. A depletion layer resulting from a junction (pn junction) of the p⁻ type relaxation layer 24 and the n⁻ type epitaxial lines 13 can therefore be formed in the entirety of the n⁻ type epitaxial lines 13. The equipotential surface of high electric potential on the basis of the gate electrode 18 can be pressed downward toward the substrate 7 side and be displaced away from the gate insulating film 17 by the depletion layer. Consequently, the electric field applied to the gate insulating film 17 can be decreased. Dielectric breakdown of the gate insulating film 17 during an HTRB test, in which a voltage approximating a device withstand voltage continues to be applied across the source and the drain, and further during actual use can thus be prevented. The semiconductor device 1 of excellent voltage resistance can thus be manufactured at high yield.

Also, in an arrangement, such as that of the present preferred embodiment, in which the n⁻ type epitaxial lines 13 are formed in a lattice, an especially strong electric field tends to be generated at each intersection portion 27 that is surrounded by the respective corners of four unit cells 10 that are arrayed in two rows and two columns. However, with the semiconductor device 1, portions (first portions 25) of the p⁻ type relaxation layer 24 larger than the intersection portions 27 are formed at the intersection portions 27 and moreover, the first portions 25 enter into the respective corners of the unit cells 10. Dielectric breakdown of the portions of the gate insulating film 17 that face the intersection portions 27 can thus be prevented effectively. Also, portions of the p⁻ type relaxation layer 24 are formed not only at the intersection portions 27 but also at portions (second portions 26) besides the intersection portions 27 so that the electric field applied to the gate insulating film 17 can be relaxed uniformly.

Also, portions (first portions 25) of the p⁻ type relaxation layer 24 are formed in the first lines 11 that are parallel to the off-direction of the substrate 7. Moreover, the first lines 11 extending across a plurality of the unit cells 10 are partitioned by the first portions 25 so that the respective lengths thereof are shorter than the length of the entirety. It was found that in this case, an increase in the on-resistance can be suppressed even if a voltage is continuously applied across the source and the drain in the gate-off state over a long period of time.

### <Other Layouts of the Unit Cells in the First Preferred Embodiment>

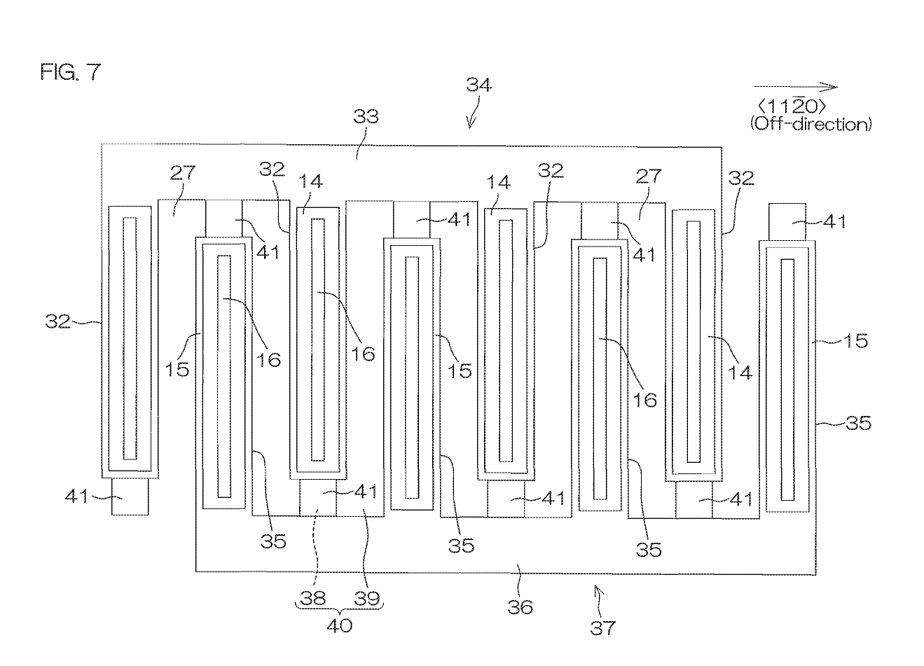

Although a plurality of other layouts of the plurality of unit cells of the semiconductor device 1 shall now be described as examples with reference to FIG. 7 to FIG. 12, the layout of the plurality of unit cells is not restricted to these examples. In FIG. 7 to FIG. 12, portions corresponding to respective portions in FIG. 1 described above shall be provided with the same reference symbols. Also, even in FIG. 7 to FIG. 12, the off-direction of the substrate 7 is, for example, the <11-20> direction.

Although in the description above, the plurality of unit cells 10 were described as being laid out in an array, a plurality of comb-type units may each be formed using a plurality of unit cells and the plurality of comb-type units may be engaged mutually as shown in FIG. 7. Specifically, a first comb-type unit 34, formed by integrally joining a plurality of unit cells 32 in a comb-teeth shape to a base portion 33, and a second comb-type unit 37, formed by integrally joining a plurality of unit cells 35 in a comb-teeth shape to a base portion 36, may be engaged mutually. In this case, the plurality of unit cells 32 and 35 may be aligned along the off-direction of the substrate 7. That is, the direction that crosses the plurality of unit cells 32 and 35 may be matched with the off-direction.

By adopting this arrangement, n⁻ type epitaxial lines 40 are formed in a winding shape so as to meander between the first comb-type unit 34 and the second comb-type unit 37. Specifically, the n⁻ type epitaxial lines 40 are formed in a continuous meandering shape in which a plurality of second lines 39, which are mutually parallel in a direction intersecting the off-direction of the substrate 7 are folded back and made continuous at respective end portions of the unit cells 32 and 35 (end portions each facing the base portion 33 or 36 of the other unit) via first lines 38 parallel to the off-direction of the substrate 7. That is, the plurality of unit cells 32 and 35 are demarcated by the n⁻ type epitaxial lines 40 including the first lines 38 and the second lines 39. The n⁻ type epitaxial lines 40 are disposed at sides of the channel regions 15.

Also, the respective unit cells 32 and 35 may be formed to oblong shapes having long sides extending along the second lines 39 and short sides extending along the first lines 38.

Also, a p⁻ type electric field relaxation layer 41 is formed in each first line 38 so as to cross the first line 38. The p⁻ type electric field relaxation layer 41 may extend across the end portion of each unit cell 35 of the second comb-type unit 37 and the base portion 33 of the first comb-type unit 34 and across the end portion of each unit cell 32 of the first comb-type unit 34 and the base portion 36 of the second comb-type unit 37.

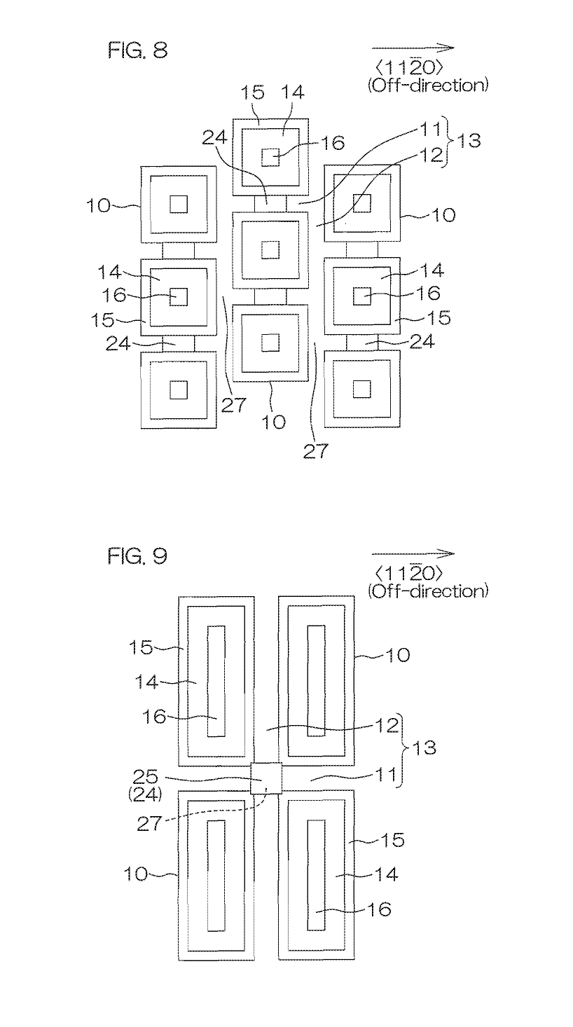

Also, as shown in FIG. 8, a plurality of unit cells 10 may be laid out in a staggered alignment in which mutually adjacent unit cells 10 are alternately dislocated along the second line 12 (along the direction intersecting the off-direction of the substrate 7). Specifically, a column, made up of a plurality of unit cells 10 that are laid out so as to be mutually spaced along the direction intersecting the off-direction of the substrate 7, may be shifted by one half of a pitch (a half pitch) of the unit cell 10 along the direction intersecting the off-direction of the substrate 7 with respect to a column mutually adjacent to the column. In this case, the p⁻ type relaxation layer 24 may be formed so as to cross the first line 11 in the width direction and partition the first line 11.

Also, as shown in FIG. 9, the respective unit cells 10 may be formed to oblong shapes having long sides extending along the second lines 12 and short sides extending along the first lines 11. Also, the p⁻ type relaxation layer 24 may be formed just at the intersection portions 27 of the first lines 11 and the second lines 12 and may be omitted at portions besides the intersection portions 27. That is, just the first portions 25 of the p⁻ type relaxation layer 24 may be formed.

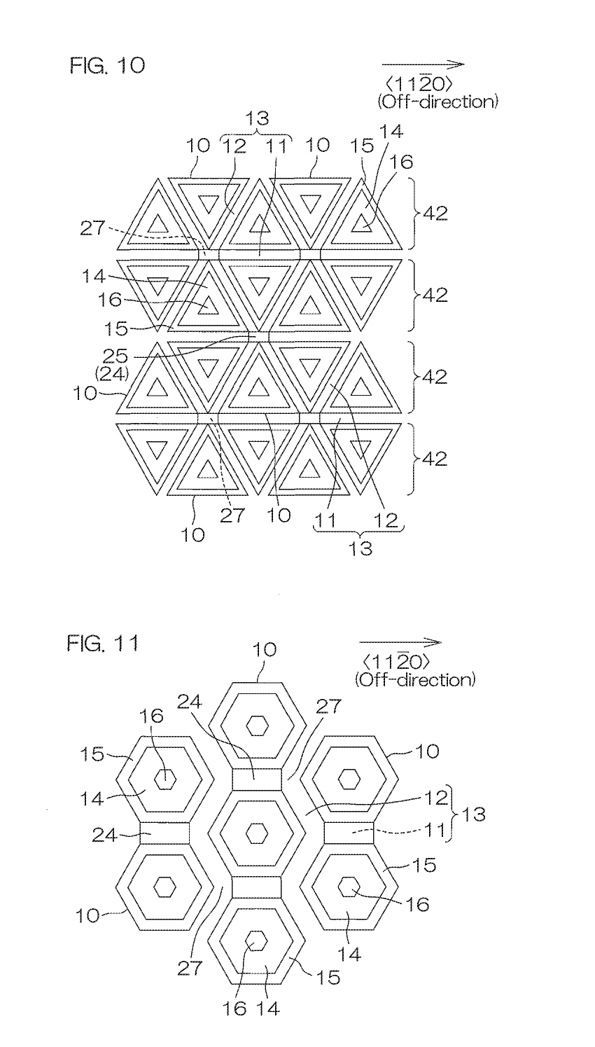

Also, as shown in FIG. 10, each unit cell 10 may be formed to a triangular shape (for example, an equilateral triangular shape). The layout pattern of the plurality of unit cells 10 may be arranged by forming truss columns 42 by combining the unit cells 10 of triangular shape alternatingly along the off-direction of the substrate 7 and aligning the truss columns 42 along the direction intersecting the off-direction of the substrate 7.

In this case, the portions between mutually adjacent truss columns 42 become the first lines 11 of the n⁻ type epitaxial lines 13 and portions between mutually adjacent unit cells 10 in each truss column 42 become the second lines 12 of the n⁻ type epitaxial lines 13. Also, the p⁻ type relaxation layer 24 may be formed just at the intersection portions 27 of the first lines 11 and the second lines 12 and may be omitted at portions besides the intersection portions 27. That is, just the first portions 25 of the p⁻ type relaxation layer 24 may be formed.

Also, as shown in FIG. 11, each unit cell 10 may be formed to a hexagonal shape (for example, a regular hexagonal shape). The layout pattern of the plurality of unit cells 10 may be a honeycomb pattern. In other words, the plurality of unit cells 10 may be laid out in a staggered alignment in which mutually adjacent unit cells 10 are alternately dislocated along the second line 12 (along the direction intersecting the off-direction of the substrate 7). In this case, the p⁻ type relaxation layer 24 may be formed to cross the first lines 11 in the width direction so as to cover the first lines 11 over the entireties of the first lines 11 (with the exception of the intersection portions 27).

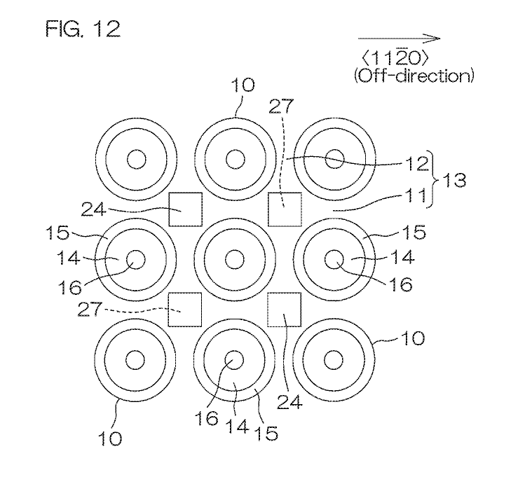

Also, as shown in FIG. 12, each unit cell 10 may be formed to a circular shape. Also, the p⁻ type relaxation layer 24 may be formed just at the intersection portions 27 of the first lines 11 and the second lines 12 and may be omitted at portions besides the intersection portions 27. That is, just the first portions 25 of the p⁻ type relaxation layer 24 may be formed.

Also, movement from each unit cell 10 by an amount corresponding to a unit or an amount corresponding to an integral multiple of a unit along the first line 11 or the second line 12 results in the next unit cell 10.

### Second Preferred Embodiment

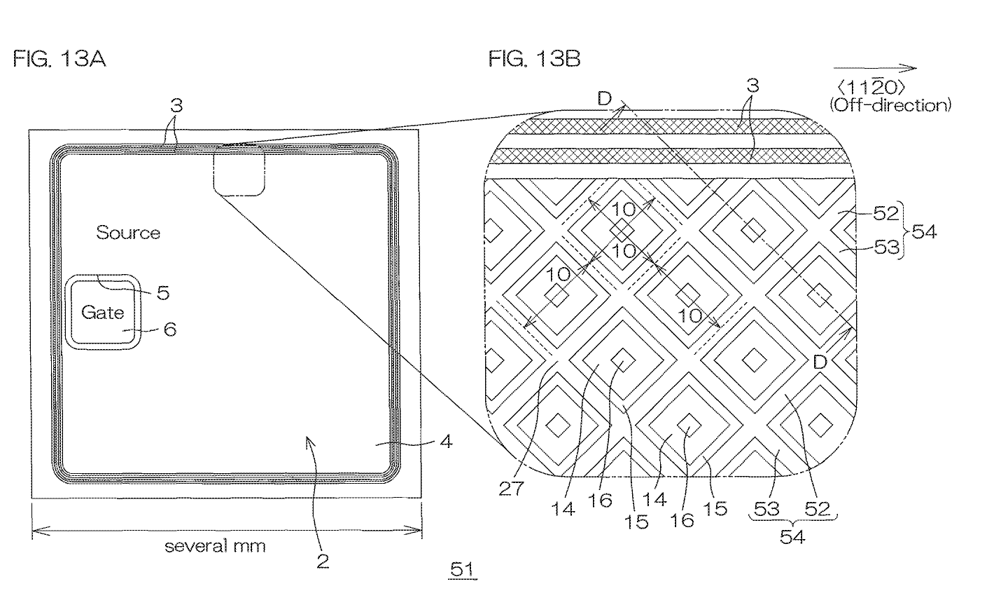

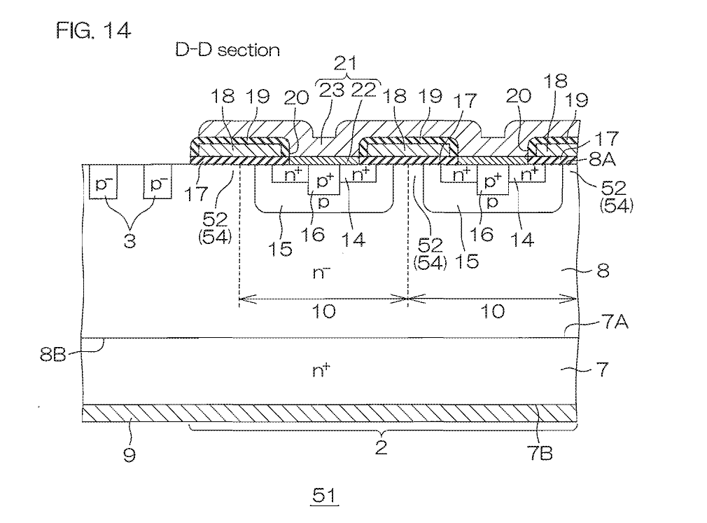

FIGS. 13A and 13B are schematic plan views of a semiconductor device according to a second preferred embodiment of the present invention, with FIG. 13A being an overall view and FIG. 13B being a layout diagram of a plurality of unit cells. FIG. 14 is a sectional view taken along sectioning line D-D in FIG. 13B. In FIG. 13B, a portion of the semiconductor device 51 is drawn transparently for the sake of clarity. Also, in FIG. 13 and FIG. 14, portions corresponding to respective portions in FIG. 1 and FIG. 2 described above shall be provided with the same reference symbols. Also, even in FIG. 13 and FIG. 14, the off-direction of the substrate is, for example, the <11-20> direction.

Although in the first preferred embodiment described above, the n⁻ type epitaxial lines 13 were arranged from the first lines 11 parallel to the off-direction of the substrate 7 and the second lines 12 intersecting the first lines 11, the n⁻ type epitaxial lines may instead be arranged from first lines and second lines that respectively intersect the off-direction of the substrate 7.

Specifically, n⁻ type epitaxial lines 54 of the present semiconductor device 51 include first lines 52 and second lines 53 that intersect the off-direction of the substrate 7. For example, the first lines 52 and the second lines 53 are inclined at 45° with respect to the off-direction of the substrate 7 and are mutually orthogonal.

With this arrangement, both the first lines 52 and the second lines 53 forming the n⁻ type epitaxial lines 54 intersect the off-direction of the substrate 7. That is, neither the first lines 52 nor the second lines 53 are parallel to the off-direction of the substrate 7. The p⁻ type relaxation layer 24 can thus be omitted in the first lines 52 and the second lines 53. That is, with the semiconductor device 51, it was found that an increase in on-resistance after continuous application of a voltage across the source and the drain for a long period of time in the gate-off state can be suppressed without having to form the p⁻ type relaxation layer 24. Also, although the inclination angle of the second lines 53 with respect to the off-direction is most preferably 45° as in the present preferred embodiment, it is not restricted thereto and a range of 30° of 60° is also preferable.

### <Other Layouts of the Unit Cells in the Second Preferred Embodiment>

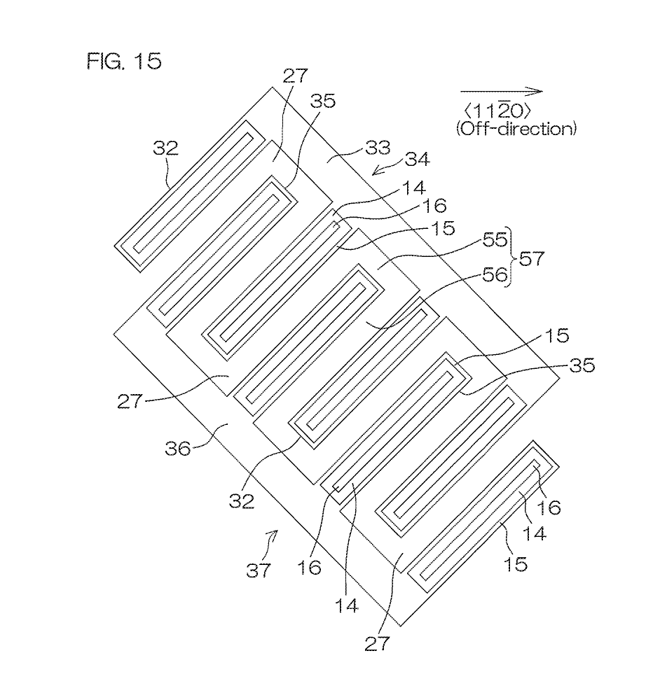

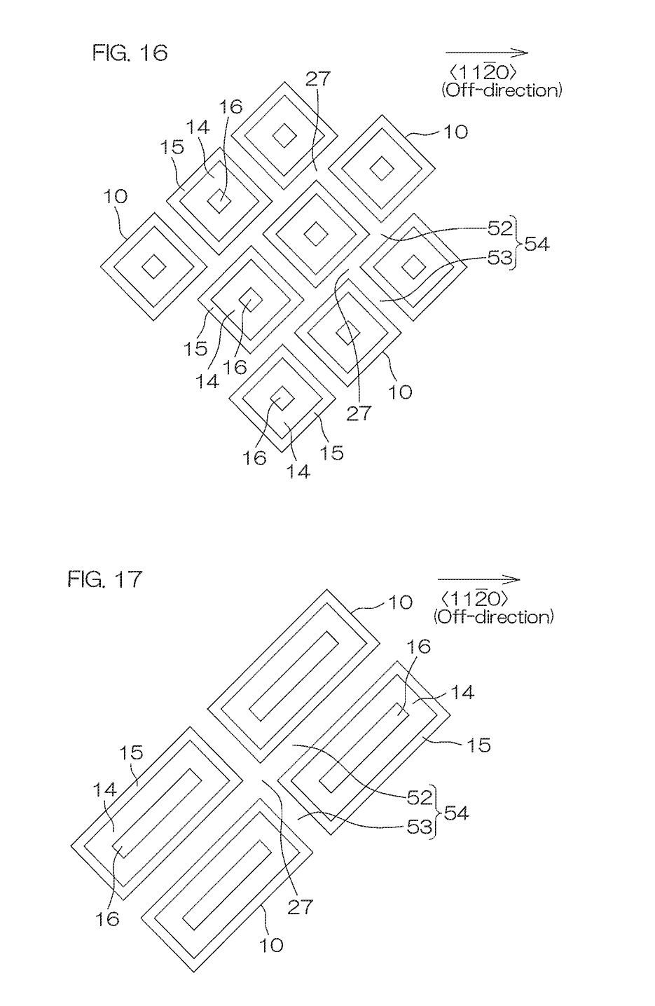

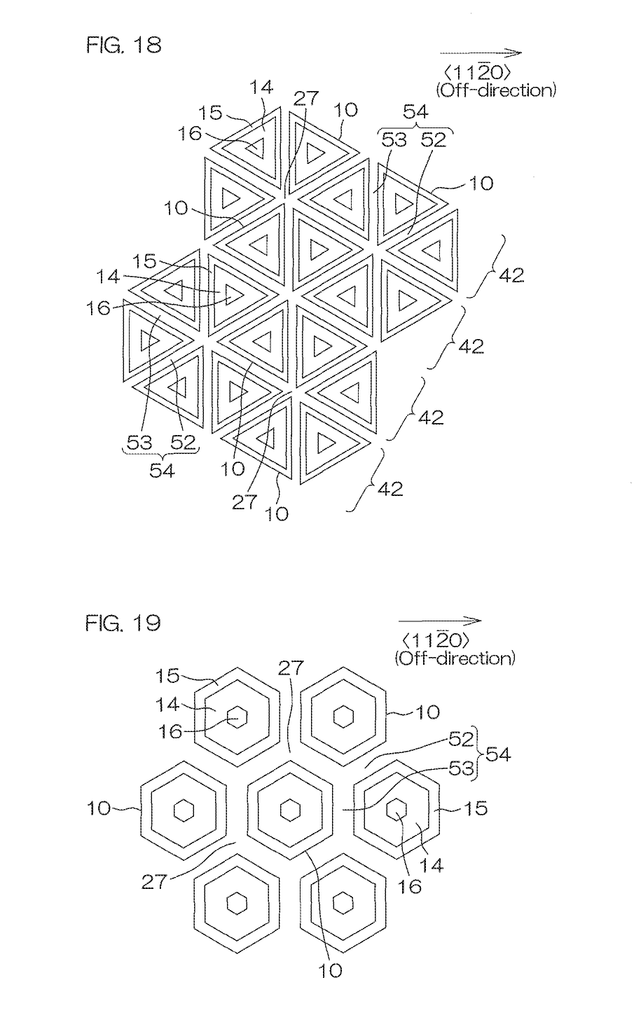

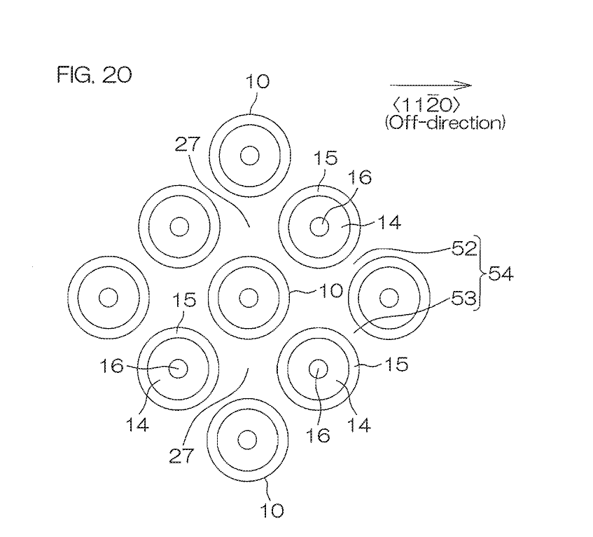

As shown in FIGS. 15 to 20, the layouts of plurality of unit cells described with reference to FIG. 7 to FIG. 12 of the first preferred embodiment may be applied to the second preferred embodiment as well. With the respective layouts of plurality of cells of FIG. 15 to FIG. 20, the layouts of plurality of cells of FIG. 7 to FIG. 12 are rotated by a predetermined angle along the front surface 7A of the substrate 7. Both the first lines 52 and the second lines 53 of the n⁻ type epitaxial lines 54 are thereby made to intersect the off-direction of the substrate 7. In FIG. 15, the arrangements corresponding to the first lines 38, the second lines 39, and the n⁻ type epitaxial lines 40 in FIG. 7 are respectively expressed as first lines 55, second lines 56, and n⁻ type epitaxial lines 57.

### Third Preferred Embodiment

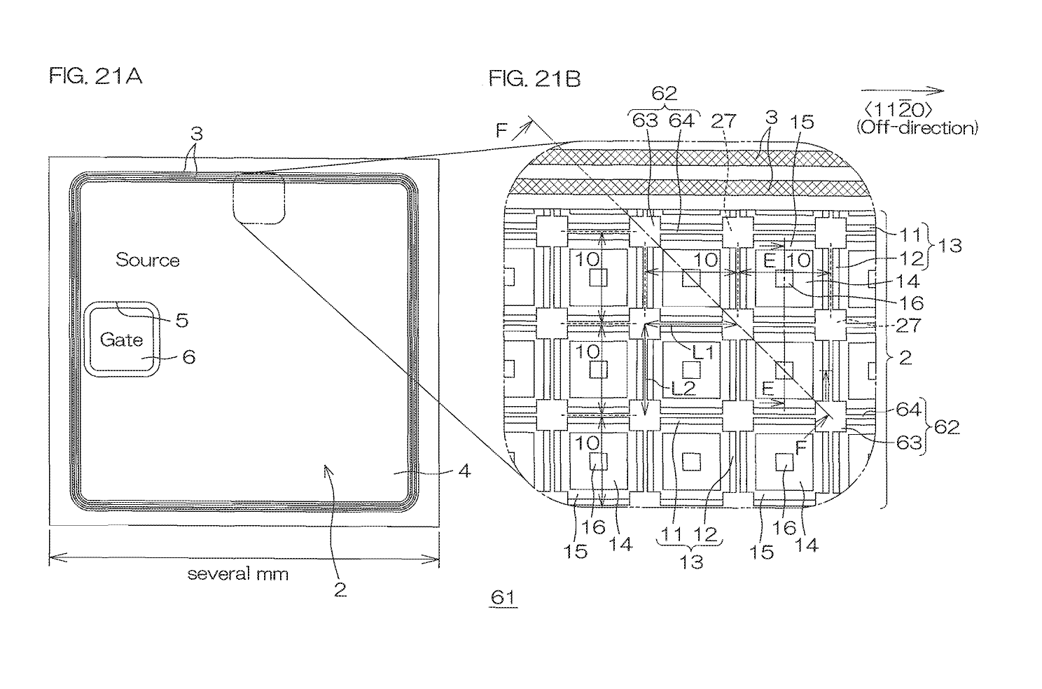

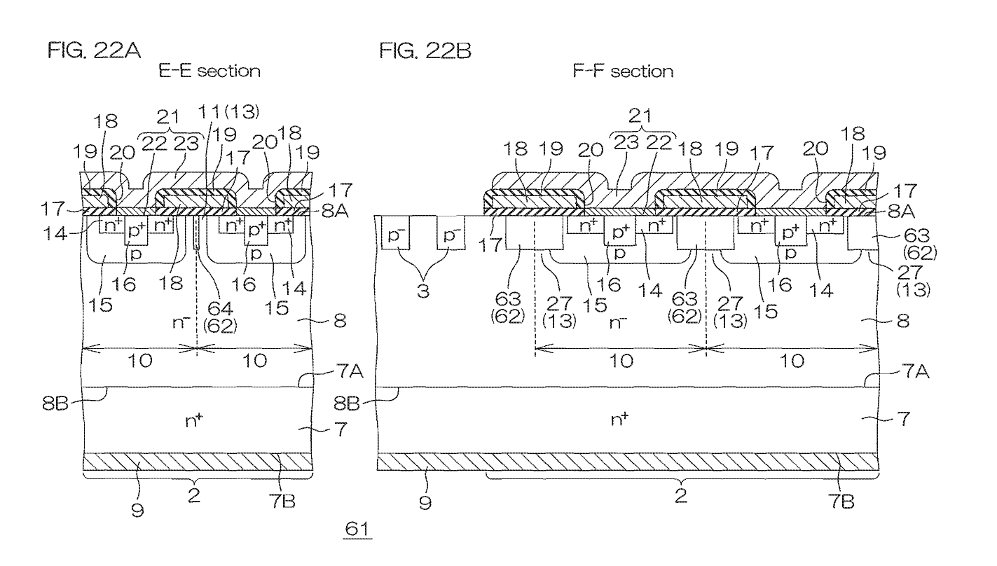

FIGS. 21A and 21B are schematic plan views of a semiconductor device according to a third preferred embodiment of the present invention, with FIG. 21A being an overall view and FIG. 21B being a layout diagram of a plurality of unit cells. FIGS. 22A and 22B are sectional views respectively taken along sectioning line E-E and sectioning line F-F in FIG. 21B. In FIG. 22B, a portion of the semiconductor device 61 is drawn transparently for the sake of clarity. Also, in FIG. 21 and FIG. 22, portions corresponding to respective portions in FIG. 1 and FIG. 2 described above shall be provided with the same reference symbols. Also, even in FIG. 21 and FIG. 22, the off-direction of the substrate 7 is, for example, the <11-20> direction.

Although in the first preferred embodiment described above, a structure with which the p⁻ type relaxation layer 24 is formed in the first lines 11 parallel to the off-direction of the substrate 7 is adopted as the structure for suppressing the increase in the on-resistance of the semiconductor device 1, another structure may be adopted as the structure for suppressing the increase in the on-resistance of a semiconductor device.

Specifically, the semiconductor device 61 includes, in the n⁻ type epitaxial lines 13, a damage layer 62 that has properties different from those of the drift layer 8. As with the p⁻ type relaxation layer 24 of the first preferred embodiment described above, the damage layer 62 integrally includes first portions 63 disposed at the intersection portions 27 of the first lines 11 and the second lines 12 and second portions 64 disposed at the linear portions (portions besides the intersection portions 27) of the first lines 11 and the second lines 12.

The damage layer 62 may, for example, be formed by applying physical damage to the front surface of the drift layer 8 by applying a treatment, such as etching (for example, using a halogen-based gas, etc.), plasma CVD (for example, plasma CVD for forming an insulating film, etc.), or sputtering (for example, using O₂, Ar, or N₂ gas, etc.), etc., at positions in the first lines 11 and second lines 12 at which the damage layer 62 is to be formed. Or, in a process of epitaxially growing the drift layer 8, the damage layer 62 may be formed across an entirety of a vicinity of the front surface 8A (a front surface portion) of the drift layer 8 by changing an epitaxial condition (for example, Si/C) from a depth position at which the damage layer 62 is to be formed.

With the present arrangement, portions (first portions 63) of the damage layer 62 are formed in the first lines 11 that are parallel to the off-direction of the substrate 7. Moreover, the first lines 11 extending across a plurality of the unit cells 10 are partitioned by the first portions 63 so that the respective lengths thereof are shorter than the length of the entirety. It was found that in this case, the increase in the on-resistance can be suppressed even if a voltage is continuously applied across the source and the drain in the gate-off state for a long period of time.

### <Other Layouts of the Unit Cells in the Third Preferred Embodiment>

Although unillustrated, the layouts of plurality of unit cells described with reference to FIG. 7 to FIG. 12 of the first preferred embodiment may be applied to the third preferred embodiment as well.

### Fourth Preferred Embodiment

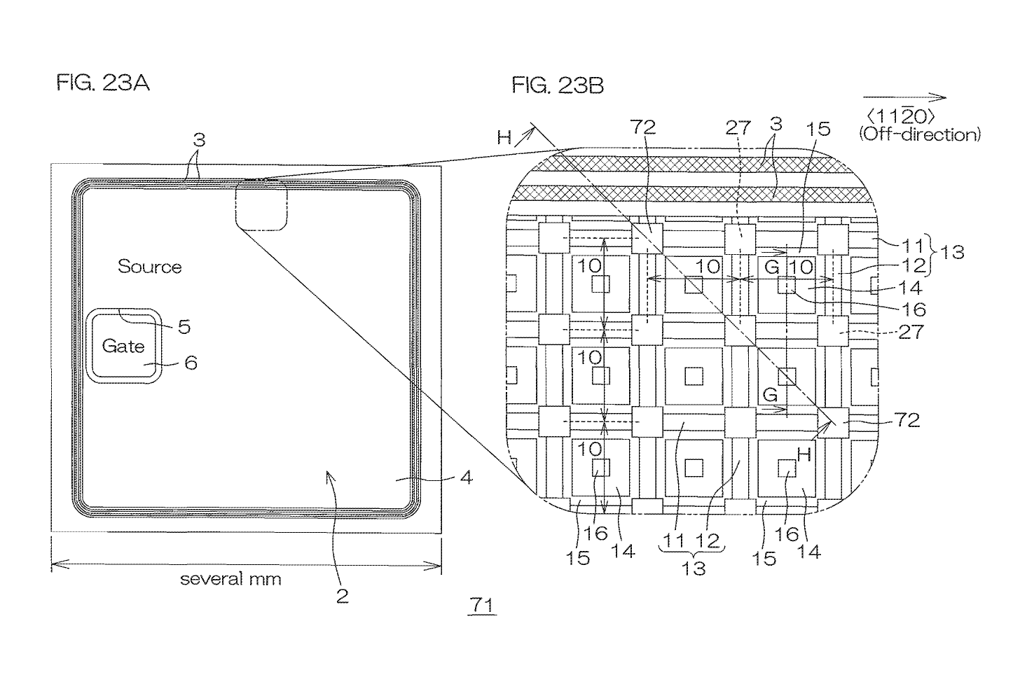

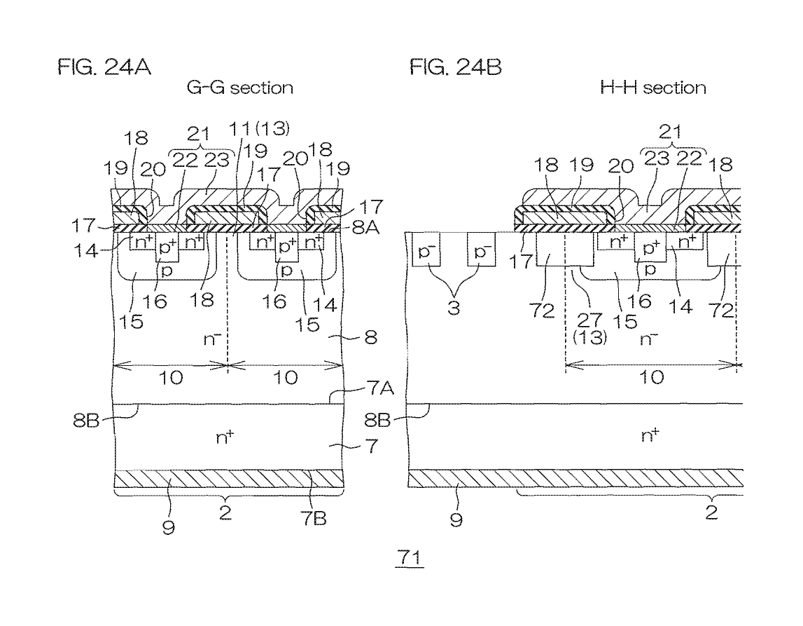

FIGS. 23A and 23B are schematic plan views of a semiconductor device according to a fourth preferred embodiment of the present invention, with FIG. 23A being an overall view and FIG. 23B being a layout diagram of a plurality of unit cells. FIGS. 24A and 24B are sectional views respectively taken along sectioning line G-G and sectioning line H-H in FIG. 23B. In FIG. 24B, a portion of the semiconductor device 71 is drawn transparently for the sake of clarity. Also in FIG. 23 and FIG. 24, portions corresponding to respective portions in FIG. 1 and FIG. 2 described above shall be provided with the same reference symbols. Also, even in FIG. 23 and FIG. 24, the off-direction of the substrate 7 is, for example, the <11-20> direction.

Although in the third preferred embodiment described above, the damage layer 62 includes the first portions 63 disposed at the intersection portions 27 of the first lines 11 and the second lines 12 and the second portions 64 disposed at the linear portions (portions besides the intersection portions 27) of the first lines 11 and the second lines 12, in the present semiconductor device 71, a damage layer 72 is disposed just at the intersection portions 27. That is, a damage layer does not have to be formed in the second lines 12.

Even in this arrangement, the damage layer 72 is formed in the first lines 11 that are parallel to the off-direction of the substrate 7. Moreover, the first lines 11 extending across a plurality of the unit cells 10 are partitioned by the damage layer 72 so that the respective lengths thereof are shorter than the length of the entirety. It was found that in this case, the increase in the on-resistance can be suppressed even if a voltage is continuously applied across the source and the drain in the gate-off state for a long period of time.

### <Other Layouts of the Unit Cells in the Fourth Preferred Embodiment>

Although unillustrated, the layouts of plurality of cells described with reference to FIG. 7 to FIG. 12 of the first preferred embodiment may be applied to the fourth preferred embodiment as well.

Although preferred embodiments of the present invention have been described above, the present invention may be implemented in other modes.

For example, arrangements in which the conductivity types of the respective semiconductor portions of the respective semiconductor devices (1, 51, and 61) are inverted may be adopted. For example, in the semiconductor device 1, a p type portion may be of an n type and an n type portion may be of a p type.

Also, the p⁻ type relaxation layer 24 or the damage layer 62 may be deeper than the channel region 15.

Also, the present invention may be applied to a MISFET with a trench gate structure.

The semiconductor device according to the present invention may, for example, be incorporated in a power module used in an inverter circuit making up a drive circuit for driving an electric motor used as a power source of an electric vehicle (including a hybrid vehicle), an electric train, an industrial robot, etc. It may also be incorporated in a power module used in an inverter circuit that converts electric power generated by a solar cell, a wind power generator, or other type of power generating apparatus (especially, a private power generating apparatus) so as to be matched with electric power generated by a commercial power source.

Also, the features ascertainable from the above disclosure of the preferred embodiments may be mutually combined even among different preferred embodiments. Also, the components illustrated in the respective preferred embodiments may be combined within the scope of the present invention. Besides the above, various design modifications may be made within the scope of the matters described in the claims.

### EXAMPLES

Although the present invention shall now be described based on an example and a comparative example, the present invention is not restricted by the example described below.

### Example 1 and Comparative Example 1

A semiconductor device with the same structure as the first preferred embodiment was manufactured (Example 1). On the other hand, a semiconductor device was manufactured by the same method as Example 1 with the exception that the p⁻ type relaxation layer 24 was not formed (Comparative Example 1).

A power of 15 W (I_{sd}=3 A, V_{sd}=5V) was continuously applied for 60 hours to the semiconductor device of Comparative Example 1 in the gate-off (V_{gx}=0) state. When the on-resistance was measured thereafter, the on-resistance was found to be increased by 1.6 times in comparison to that before the application of power.

A power of 48 W (I_{sd}=8 A, V_{sd}=6V) was continuously applied for 1000 hours to the semiconductor device of Example 1 in the gate-off (V_{gs}=0) state. When the on-resistance was measured thereafter, the on-resistance was found to be increased only by 1.1 times in comparison to that before the application of power.

From the above, it was found that with the arrangement in which the p⁻ type relaxation layer 24 is formed in the first lines 11 parallel to the off-direction of the substrate 7, the increase in the on-resistance can be suppressed even if a voltage is continuously applied across the source and the drain in the gate-off state for a long period of time.

### DESCRIPTION OF REFERENCE SIGNS

1 Semiconductor device
7 Substrate
7A Front surface
7B Rear surface
8 Drift layer
8A Front surface
10 Unit cell
11 First line
12 Second line
13 n⁻ type epitaxial line
14 Source region
15 Channel region
17 Gate insulating film
18 Gate electrode
24 p⁻ type relaxation layer
25 First portion
26 Second portion
27 Intersection portion
32 Unit cell
34 First comb-type unit
35 Unit cell
37 Second comb-type unit
38 First line
39 Second line
40 n⁻ type epitaxial line
41 p⁻ type relaxation layer
51 Semiconductor device
52 First line
53 Second line
54 n⁻ type epitaxial line
55 First line
56 Second line
57 n⁻ type epitaxial line
61 Semiconductor device
62 Damage layer
63 First line
64 Second line
71 Semiconductor device
72 Damage layer

1. A semiconductor device comprising:
a substrate made of a first conductivity type SiC and having a predetermined off-angle;
an epitaxial layer made of a first conductivity type SiC and formed on a front surface of the substrate;
a plurality of unit cells demarcated in the epitaxial layer by first conductivity type epitaxial lines including a first line parallel to an off-direction of the substrate and a second line intersecting the first line, and each line having a first conductivity type source region forming a portion of a front surface of the epitaxial layer, and a second conductivity type channel region formed on a rear surface side of the epitaxial layer with respect to the source region so as to contact the source region and forming a portion of the front surface of the epitaxial layer;
a gate insulating film formed on the front surface of the epitaxial layer;
a gate electrode formed on the gate insulating film and facing the channel region across the gate insulating film; and
an electric field relaxation portion formed in the first line in the epitaxial layer and relaxing an electric field generated in the gate insulating film.

2. The semiconductor device according to claim 1, wherein the electric field relaxation portion is formed so as to cross the first line in a width direction to selectively partition the first line.

3. The semiconductor device according to claim 2, wherein the length of each partitioned first line is no more than the length of the second line.

4. The semiconductor device according to claim 1, wherein the electric field relaxation portion is disposed at an intersection portion of the first line and the second line.

5. The semiconductor device according to claim 4, wherein the electric field relaxation portion that is disposed at the intersection portion is overlapped with the channel region in plan view.

6. The semiconductor device according to claim 1, wherein the electric field relaxation portion is formed along the first line and to have a width narrower than the width of the first line.

7. The semiconductor device according to claim 1, wherein the electric field relaxation portion is a second conductivity type relaxation layer formed by introducing impurity ions of a second conductivity type into the first line.

8. The semiconductor device according to claim 7, wherein the second conductivity type relaxation layer contains aluminum (Al) or boron (B) as the second conductivity type impurity ions.

9. The semiconductor device according to claim 7, wherein the second conductivity type relaxation layer is made high in resistance.

10. The semiconductor device according to claim 9, wherein the second conductivity type relaxation layer that has been made high in resistance contains aluminum (Al), boron (B), argon (Ar), or vanadium (V) as the second conductivity type impurity ions.

11. The semiconductor device according to claim 1, comprising: a first comb-type unit formed by integrally joining a plurality of unit cells in a comb-teeth shape; and
a second comb-type unit formed by integrally joining a plurality of unit cells in a comb-teeth shape and engaging with the first comb-type unit; and
wherein the first conductivity epitaxial lines are formed in a winding shape so as to meander between the first comb-type unit and second comb-type unit.

12. The semiconductor device according to claim 1, wherein the plurality of unit cells are in a staggered alignment in which mutually adjacent unit cells are alternately dislocated along the second line.

13. The semiconductor device according to claim 1, wherein each unit cell is formed to a square shape.

14. The semiconductor device according to claim 1, wherein each unit cell is formed to an oblong shape having a long side extending along the second line and a short side extending along the first line.

15. The semiconductor device according to claim 1, wherein each unit cell is formed to a hexagonal shape.

16. The semiconductor device according to claim 1, wherein each unit cell is formed to a triangular shape.

17. The semiconductor device according to claim 1, wherein each unit cell is formed to a circular shape.

18. A semiconductor device comprising:
a substrate made of a first conductivity type SiC and having a predetermined off-angle;
an epitaxial layer made of a first conductivity type SiC and formed on a major surface of the substrate;
a plurality of unit cells demarcated in the epitaxial layer by first conductivity type epitaxial lines including a first line and a second line respectively intersecting the off-direction of the substrate and intersecting each other, and each line having a first conductivity type source region forming a portion of a front surface of the epitaxial layer, and a second conductivity type channel region formed on a rear surface side of the epitaxial layer with respect to the source region so as to contact the source region and forming a portion of the front surface of the epitaxial layer;
a gate insulating film formed on the front surface of the epitaxial layer; and
a gate electrode formed on the gate insulating film and facing the channel region across the gate insulating film.

19. A semiconductor device comprising:
a substrate made of a first conductivity type SiC and having a predetermined off-angle;
an epitaxial layer made of a first conductivity type SiC and formed on a front surface of the substrate;
a plurality of unit cells demarcated in the epitaxial layer by first conductivity type epitaxial lines including a first line parallel to an off-direction of the substrate and a second line intersecting the first line, and each line having a first conductivity type source region forming a portion of a front surface of the epitaxial layer, and a second conductivity type channel region formed on a rear surface side of the epitaxial layer with respect to the source region so as to contact the source region and forming a portion of the front surface of the epitaxial layer;
a gate insulating film formed on the front surface of the epitaxial layer;
a gate electrode formed on the gate insulating film and facing the channel region across the gate insulating film;
and a damage layer formed on the first line in the epitaxial layer having properties different from those of other portions of the epitaxial layer.

20. The semiconductor device according to claim 1, wherein the off-direction of the substrate is the <11-20> direction.
